(19) United States
(12) Patent Application Publication
(10) Pub. No.: US 2022/0399277 A1
(43) Pub. Date: Dec. 15, 2022

(54) SELECTIVE ROUTING THROUGH INTRA-CONNECT BRIDGE DIES

(71) Applicant: INTEL CORPORATION, Santa Clara, CA (US)

(72) Inventors: Adel A. Elsherbini, Tempe, AZ (US); Scott E. Siers, Elk Grove, CA (US); Sathya Narasimman Tiagaraj, San Jose, CA (US); Gerald S. Pasdast, San Jose, CA (US); Zhiguo Qian, Chandler, AZ (US); Kalyan C. Kolluru, Portland, OR (US); Vivek Kumar Rajan, Portland, OR (US); Shawna M. Liff, Scottsdale, AZ (US); Johanna M. Swan, Scottsdale, AZ (US)

(73) Assignee: INTEL CORPORATION, Santa Clara, CA (US)

(21) Appl. No.: 17/345,969

(22) Filed: Jun. 11, 2021

(51) Int. Cl. H01L 23/538; H01L 25/065; H01L 23/00; H01L 21/48; H01L 25/00

(52) U.S. Cl. CPC H01L 23/5381; H01L 25/0657; H01L 24/08; H01L 23/5386; H01L 23/5389; H01L 21/4853; H01L 24/80; H01L 25/50; H01L 2225/06517; H01L 2225/06548; H01L 2225/06572; H01L 2224/08235; H01L 2224/80895; H01L 2224/80896

(57) ABSTRACT

An Integrated Circuit (IC), comprising a first conductive trace on a first die, a second conductive trace on a second die, and a conductive pathway electrically coupling the first conductive trace with the second conductive trace. The second die is coupled to the first die with interconnects. The conductive pathway comprises a portion of the interconnects located proximate to a periphery of a region in the first die through which the first conductive trace is not routable. In some embodiments, the conductive pathway reroutes electrical connections away from the region. The region comprises a high congestion zone having high routing density in some embodiments. In other embodiments, the region comprises a “keep-out” zone.

### TECHNICAL FIELD

The present disclosure relates to techniques, methods, and apparatus directed to selective routing through intra-connect bridge dies.

### BACKGROUND

Electronic circuits when fabricated on a wafer of semiconductor material, such as silicon, are commonly called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a schematic cross-sectional view of an example IC packaging architecture, according to some embodiments of the present disclosure.

FIG. 2 is a schematic exploded isometric view of an example microelectronic assembly, according to some embodiments of the present disclosure.

FIG. 3 is a schematic cross-sectional view of yet another example IC packaging architecture, according to some embodiments of the present disclosure.

FIG. 4 is a schematic cross-sectional view of yet another example IC packaging architecture, according to some embodiments of the present disclosure.

FIG. 5 is a schematic cross-sectional view of yet another example IC packaging architecture, according to some embodiments of the present disclosure.

FIG. 6 is a schematic cross-sectional view of yet another example IC packaging architecture, according to some embodiments of the present disclosure.

FIG. 7 is a schematic view of an example routing, according to some embodiments of the present disclosure.

FIG. 8 is a schematic view of another example routing according to some embodiments of the present disclosure.

FIG. 9 is a schematic view of yet another example routing according to some embodiments of the present disclosure.

FIG. 10 is a flow diagram of an example method of fabricating a microelectronic assembly, according to various embodiments of the present disclosure.

FIG. 11 is a cross-sectional view of a device package that may include one or more IC packages in accordance with any of the embodiments disclosed herein.

FIG. 12 is a cross-sectional side view of a device assembly that may include one or more IC packages in accordance with any of the embodiments disclosed herein.

FIG. 13 is a block diagram of an example computing device that may include one or more IC packages in accordance with any of the embodiments disclosed herein.

### DETAILED DESCRIPTION

### Overview

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in any way to limit the broad scope of the present disclosure and its potential applications.

In a general sense, a die consists of two regions: a front-end-of-line (FEOL) region comprising active devices such as transistors and diodes in a substrate, and a back-end-of-line (BEOL) region comprising a metallization stack having many layers of dielectric and conductive traces enabling electrical connectivity to the FEOL. Signals in such dies are routed on these conductive traces. The routing density is a function of line pitch and number of routing layers. In new technology devices, routing density demands are high due to higher packing density of active logic circuits and devices, and increased data rates needed by advanced processors termed XPUs, such as central processing units (CPUs), general processing units (GPUs), etc. This results in relatively tall metal stacks with a large number of layers to support the required routing. The tall metal stacks may not be well utilized or suited for various applications due to multiple reasons. For example, not all routing resources are needed everywhere; in other words, only power delivery resources are typically needed over processing cores due to relatively small number of connections over the core area. In other cases, there may be a bottleneck in routing, for example, due to “keep-out zones” on the die that are reserved for certain logic circuits such as voltage regulators (VRs), which create electrical interference issues for traces formed over the VR. This requires a taller metal stack to reach the needed routing density in these bottleneck regions, but the taller metal stack is not utilized elsewhere in the die. In addition, the additional metal layers require additional processing steps, increasing the cost, impacting the yield, and possibly impacting power delivery over higher power regions of the die due to additional resistance from the longer routing distance from the larger number and increased thickness of top metal layers.

On-die serializer/de-serializer (SerDes) may be used to mitigate routing congestion to a certain extent. The SerDes circuit converts multiple streams of data into a serial stream of data that is transmitted over a high-speed connection, such as low-voltage differential signaling (LVDS) to a receiver that converts the serial stream back to the original streams of data. This solution does not require adding additional metal layers, but it requires adding additional circuits on the die which may increase the die area and power consumption, and for data movement power sensitive applications such as artificial intelligence (Al) it may reduce compute efficiency. It may also add latency for latency sensitive workloads such as server stacks.

In one aspect of the present disclosure, an example of selective routing with intra-connect “jump over” bridge dies (also referred to herein as “jump over die” or JOD) includes an IC comprising a first conductive trace in a first die, a second conductive trace in a JOD, and a conductive pathway electrically coupling the first conductive trace with the second conductive trace. The JOD is coupled to the first die with interconnects, the conductive pathway comprises a portion of the interconnects located proximate to a periphery of a region in the first die through which the first conductive trace is not routable. In some embodiments, the conductive pathway through the JOD reroutes electrical connections away from the region. As used herein, the “region” encompasses a three-dimensional volume. Because the interconnects are located on a surface, the “periphery” of this three-dimensional volume on the surface comprises a linear perimeter formed by the projection of this volume on the surface. In some embodiments, the interconnects may comprise hybrid bond interconnects. As used herein, “hybrid bond interconnects” comprises die-to-die (DTD) interconnects with sub-10 micrometer pitch. In other words, the minimum separation between any two hybrid bond interconnects is less than or equal to 10 micrometers.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices. The term “circuit” means one or more passive and/or active components that are arranged to cooperate with one another to provide a desired function. The term “interconnect” may be used to describe any element formed of an electrically conductive material for providing electrical connectivity to one or more components associated with an IC or/and between various such components. In general, the “interconnect” may refer to both conductive traces (also sometimes referred to as “lines”) and conductive vias. In general, in context of interconnects, the term “conductive trace” may be used to describe an electrically conductive element isolated by an insulating material (e.g., a low-k dielectric material) that is provided within the plane of a die. Such traces are typically stacked into several levels, or several layers, of metallization stacks. On the other hand, the term “via” may be used to describe an electrically conductive element that interconnects two or more traces at different levels. To that end, a via may be provided substantially perpendicularly to the plane of a die and may interconnect two traces in adjacent levels or two traces in not adjacent levels. A term “metallization stack” may be used to refer to a stack of one or more interconnects for providing connectivity to different circuit components of a die. Sometimes, traces and vias may be referred to as “conductive traces” and “conductive vias”, respectively, to highlight the fact that these elements include electrically conductive materials such as metals.

Interconnects as described herein, in particular interconnects of the IC structures as described herein, may be used for providing electrical connectivity to one or more components associated with an IC or/and between various such components, where, in various embodiments, components associated with an IC may include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer. In another example, the terms “package” and “IC package” are synonymous, as are the terms “die” and “IC die,” the term “insulating” means “electrically insulating,” the term “conducting” means “electrically conducting,” unless otherwise specified.

In yet another example, if used, the terms “oxide,” “carbide,” “nitride,” etc. refer to compounds containing, respectively, oxygen, carbon, nitrogen, etc., the term “high-k dielectric” refers to a material having a higher dielectric constant than silicon oxide, while the term “low-k dielectric” refers to a material having a lower dielectric constant than silicon oxide.

The terms “substantially,” “close,” “approximately,” “near,” and “about,” generally refer to being within +/−20% of a target value (e.g., within +/−5 or 10% of a target value) based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers. In addition, the term “dispose” as used herein refers to position, location, placement, and/or arrangement rather than to any particular method of formation.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. When used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

In the drawings, a particular number and arrangement of structures and components are presented for illustrative purposes and any desired number or arrangement of such structures and components may be present in various embodiments. Further, the structures shown in the figures may take any suitable form or shape according to material properties, fabrication processes, and operating conditions.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### Example Embodiments

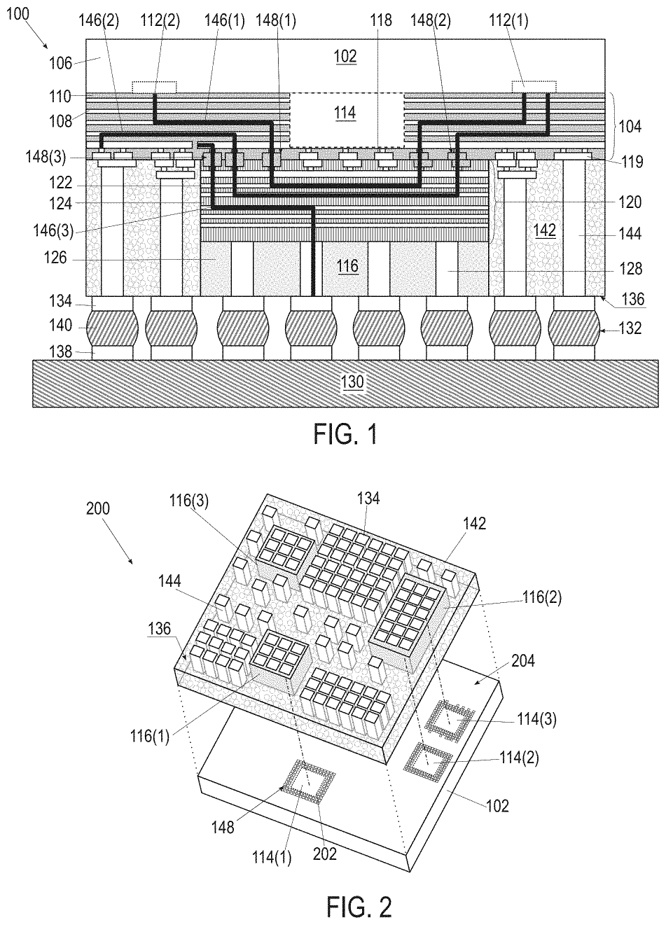

FIG. 1 is a schematic cross-sectional illustration of an IC package 100, according to some embodiments of the present disclosure. A die 102 comprises a metallization stack 104 on a substrate 106. Metallization stack 104 comprises conductive traces 108 in a plurality of insulating layers 110. Conductive vias (not shown) may facilitate electrical coupling between conductive traces 108 in metallization stack 104. Logic circuits 112 (e.g., 112(1) and 112(2)) may be situated in substrate 106. Any of conductive traces 108 and/or conductive vias may be formed of any appropriate conductive material, such as copper, silver, nickel, gold, aluminum, or other metals or alloys, for example. Conductive traces 108 may provide electrical coupling to logic circuits 112, for example, providing power, ground, and signal connections thereto. In various embodiments, conductive traces 108 may be interconnected appropriately to route power, ground and/or signals to/from various components of IC package 100.

In some embodiments, plurality of insulating layers 110 may include a dielectric material, such as silicon dioxide, silicon nitride, silicon carbon nitride, silicon carbide, oxynitride, polyimide materials, glass reinforced epoxy matrix materials, or a low-k or ultra-low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, plurality of insulating layers 110 may include a semiconductor material, such as silicon, germanium, or a III-V material (e.g., gallium nitride), and one or more additional materials. For example, plurality of insulating layers 110 may include silicon oxide or silicon nitride.

Die 102 may further comprise a blockage region 114, which is a three-dimensional volume extending through at least a portion of metallization stack 104. In some embodiments, blockage region 114 may comprise a zone of high routing density. In some other embodiments, blockage region 114 may comprise a “keep-out” zone reserved for certain logic circuits such as voltage regulators. In yet other embodiments, blockage region 114 may comprise a high bottleneck or congestion zone, for example, through which conductive traces of many logic circuits pass. In various embodiments, blockage region 116 may comprise a region through which at least some conductive traces 108 may not be routable.

In various embodiments, another die, JOD 116, may be mechanically and electrically coupled to die 102 with DTD interconnects 118 proximate to blockage region 114. In some embodiments, JOD 116 may be located in a shadow of blockage region 114. As used herein, the term “shadow” of blockage region 114 refers to a location underneath or above blockage region 114 (e.g., depending on whether JOD 116 is coupled beneath or above die 102 respectively), with a size and bounding shape corresponding to the size and bounding shape of blockage region 114. In other words, the shadow forms an area projection of blockage region 114 on the surface of die 102 to which JOD 116 is coupled.

In various embodiments, DTD interconnects 118 may be formed during hybrid bonding, which establishes metal-to-metal bonding (e.g., Cu—Cu bond), oxide bonding, or fusion bonding at the respective surfaces of die 102 and JOD 116. DTD interconnects 118 may be formed by any suitable process, for example, direct bond interconnect (DBI) technology, or other metal and oxide bonding techniques known in the art. Such DTD interconnects 118 can allow a large number of interconnections (e.g., 1000 connections/mm², 10,000 connections/mm², etc.) between die 102 and JOD 116. DTD interconnects 118 in general are relatively short, for example, compared to micro-bumps. In some embodiments, a pitch between two neighboring DTD interconnects 118 can be extremely small, for example, less than 10 micrometers. This high pitch allows for a large number of interconnections between die 102 and JOD 116. In various embodiments, DTD interconnects 118 comprise conductive metal pads (also called bond pads) 119 surrounded by plurality of insulating layers 110.

In a general sense, JOD 116 comprises a metallization stack 120 with metal layers 122 in a plurality of insulating layers 124. In various embodiments, plurality of insulating layers 124 may comprise oxides of semiconductors (e.g., silicon dioxide SiO₂), low-k dielectrics, and/or organic dielectrics. In some embodiments, JOD 116 may further comprise a substrate 126. For example, JOD 116 may be fabricated on a semiconductor wafer, using known techniques in the art, in which case, substrate 126 may comprise the semiconductor material. In some embodiments wherein substrate 126 is present, through-substrate vias (TSVs) 128 may be formed in substrate 126, for example, to facilitate electrical coupling with a package support 130 through die-to-package-substrate (DTPS) interconnects 132. DTPS interconnects 132 may comprise bond pads 134 on a surface 136, bond pads 138 on a parallel surface of package support 130 and solder balls 140. In various embodiments, JOD 116 may be surrounded by an insulator 142, for example, comprising an organic dielectric material, such as epoxy with silica fillers. Through-dielectric vias (TDVs) 144 in dielectric 142 may facilitate electrical coupling between die 102 and package support 130 through DTPS interconnects 132 and DTD interconnects 118.

In various embodiments, a first conductive trace 108 in die 102 may be electrically coupled to a second conductive trace 122 in JOD 116 by a conductive pathway 146 that facilitates rerouting first conductive trace 108 away from blockage region 114. Conductive pathway 146 comprises a portion 148 of DTD interconnects 118 located proximate to a periphery of blocked off-region 114. In a general sense, conductive pathway 146 may further include vias and passives, which are not shown so as to not clutter the drawing. In addition, more than one conductive pathway 146 may be interconnected to one another in any suitable manner.

For example, conductive pathway 146(1) may electrically couple logic circuit 112(1) with logic circuit 112(2) using conductive trace 108 in die 102, conductive trace 122 in JOD 116 and a portion 148(1) of DTD interconnects 118 located proximate to the periphery of blocked off-region 114, thereby avoiding routing in die 102 through blockage region 114. In another example, conductive trace 146(2) may provide power from outside die 102 (for example, through DTD interconnects 118 electrically coupled to TDV 144 in insulator 142) to logic circuit 112(1) and may include another portion 148(2) of DTD interconnects 118 located proximate to the periphery of blocked off-region 114. Thus, in these embodiments, metallization stack 120 of JOD 116 facilitates a discrete, localized taller metallization stack for die 102 at blockage region 114. In yet another example, conductive pathway 146(3) may provide signals to/from die 102 through conductive trace 108, yet another portion 148(3) of DTD interconnects 118 located proximate to the periphery of blocked off-region 114, conductive trace 122, and TSV 128 to package support 130 through DTPS interconnects 132 located in a shadow of blockage region 114. Conductive pathway 146(3) may avoid blockage region 114, thereby enabling additional routing pathways in and out of die 102 that would be otherwise unavailable because of blockage region 114. Although FIG. 1 illustrates a specific number and arrangement of conductive pathway 146 formed by conductive traces 108 and 122 and DTD interconnects 118, these are simply illustrative, and any suitable number and arrangement may be used.

In various embodiments, JOD 116 may be coupled to die 102 over blockage region 114. JOD 116 provides additional routing resources to avoid congestion, routing blockage and/or any other factors that may be mitigated by rerouting. DTD interconnects 118 that enable interconnections between die 102 and JOD 116 with tight pitches of the order of a few micrometers serves to avoid any vertical interconnect density bottleneck. JOD 116 may be placed where needed, which could avoid adding additional routing layers over the entirety of die 102. This selective routing and attachment could save cost, improve yield, and minimal negative impact on power delivery performance.

In some embodiments, IC structures in JOD 116 may only include conductive traces 122 and conductive vias (not shown) sufficient to form one or more conductive pathway 146 and may not contain active or passive circuitry. In other embodiments, IC structures in JOD 116 may include active or passive circuitry (e.g., transistors, diodes, resistors, inductors, and capacitors, among others). In such embodiments, signal integrity or power of the microelectronic assembly may be improved, for example, if optimized device processes and metal stacks are used. In various embodiments, JOD 116 may function as an intra-connect bridge die providing additional routing mechanisms for a single die (as opposed to an interconnect bridge die that provides routing between two different dies) situated at targeted locations (e.g., proximate to blockage region 114) for selective routing (e.g., for routing select conductive pathways around blockage region 114) to achieve various ends, such as relieving congestion, facilitating faster signal transmission, etc.

In some embodiments, JOD 116 may comprise a TSV die (e.g., as shown in the figure) comprising TSVs 128 through substrate 126, facilitating through-connections to power die 102. In other embodiments, JOD 116 may comprise a TSV-less die, for example, to reduce manufacturing cost or if blockage region 114 is low power or does not need direction electrical connections to package support 130.

In some embodiments, substrate 126 of JOD 116 may comprise substantially monocrystalline semiconductors, such as silicon or germanium. In some other embodiments, substrate 126 may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. In yet other embodiments, substrate 126 may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, substrate 126 may comprise an intrinsic IV or III-V semiconductor material or alloy, not intentionally doped with any electrically active impurity; in alternate embodiments, nominal impurity dopant levels may be present. In still other embodiments, substrate 126 may comprise be organic materials such as silica-filled epoxy. In other embodiments, substrate 126 may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, substrate 126 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc.

In various embodiments, one or both of die 102 and JOD 116 may include, or be a part of, one or more of a central processing unit, a memory device, e.g., a high-bandwidth memory device, a logic circuit, input/output circuitry, a transceiver such as a field programmable gate array transceiver, a gate array logic such as a field programmable gate array logic, of a power delivery circuitry, a III-V or a 111-N device such as a 111-N or 111-N amplifier (e.g., GaN amplifier), Peripheral Component Interconnect Express (PCIe) circuitry, Double Data Rate transfer circuitry, or other electronic components known in the art.

Although not specifically shown in all of the present illustrations in order to not clutter the drawings, when DTD or DTPS interconnects are described, a surface of a first die (e.g., die 102) may include a first set of conductive contacts, and a surface of a second die (e.g., JOD 116) or a package support may include a second set of conductive contacts. One or more conductive contacts of the first set may then be electrically and mechanically coupled to some of the conductive contacts of the second set by the DTD or DTPS interconnects. In some embodiments, the pitch of the DTD interconnects (e.g., 118) may be different from the pitch of the DTPS interconnects (e.g., 132), although, in other embodiments, these pitches may be substantially the same. In some embodiments, the DTPS interconnects disclosed herein may have a pitch between about 80 micrometer and 300 micrometer, while the DTD interconnects disclosed herein may have a pitch between about 0.7 micrometer and 100 micrometer.

The DTPS interconnects (e.g., 132) disclosed herein may take any suitable form. In some embodiments, a set of DTPS interconnects may include solder (e.g., solder bumps or balls that are subject to a thermal reflow to form the DTPS interconnects). DTPS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTPS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, some or all of the DTD interconnects as described herein may comprise DTD interconnects 118 such as hybrid bond interconnects, metal-to-metal interconnects (e.g., copper-to-copper interconnects, or plated interconnects). In other embodiments, the DTD interconnects may be solder bumps (e.g., C4 bumps) or micro-bumps (e.g., C2 bumps). In embodiments where DTD interconnects comprise metal-to-metal bonds, the conductive contacts on either side of the DTD interconnect may be bonded together (e.g., under elevated pressure and/or temperature) without the use of intervening solder or an anisotropic conductive material. In some embodiments, a thin cap of solder may be used in a metal-to-metal interconnect to accommodate planarity, and this solder may become an intermetallic compound during processing. In some metal-to-metal interconnects that utilize hybrid bonding, a dielectric material (e.g., silicon oxide, silicon nitride, silicon carbide, or an organic layer) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure.

In some embodiments, the ICs on either side of a set of DTD interconnects may be unpackaged dies, and/or the DTD interconnects may include small conductive bumps or pillars (e.g., copper bumps or pillars) attached to the respective conductive contacts by solder. In some embodiments, some or all of the DTD interconnects may be solder interconnects that include a solder with a higher melting point than a solder included in some or all of the DTPS interconnects. For example, when the DTD interconnects are formed before the DTPS interconnects are formed, solder-based DTD interconnects may use a higher-temperature solder (e.g., with a melting point above 200 degrees Celsius), while the DTPS interconnects may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth) or tin, silver, and bismuth. In some embodiments, a lower-temperature solder may include indium, indium and tin, or gallium.

In some embodiments, a set of DTD interconnects may include any appropriate solder material, such as any of the materials discussed above for the DTPS interconnects. In some embodiments, a set of DTD interconnects may include an anisotropic conductive material, such as any of the materials discussed above for the DTPS interconnects. In some embodiments, the DTD interconnects may be used as data transfer lanes, while the DTPS interconnects may be used for power and ground lines, among others. Note that in FIG. 1 and in subsequent figures, the DTD and DTPS interconnects are shown as aligned at the respective interfaces merely for ease of illustration; in actuality, some or all of them may be misaligned. In addition, there may be other components, such as bond pads, landing pads, metallization, etc. present in the assembly that are not shown in the figures to prevent cluttering. For example, through-connections may have pads on top of them and may land on larger pads on the top dies.

In packages as described herein, some or all of the DTD interconnects may have a finer pitch than the DTPS interconnects. In some embodiments, the DTD interconnects may have too fine a pitch to couple to the package substrate directly (e.g., too fine to serve as DTPS interconnects). The DTD interconnects may have a smaller pitch than the DTPS interconnects due to the greater similarity of materials in the different dies on either side of a set of DTD interconnects than between a die and a package support on either side of a set of DTPS interconnects. In particular, the differences in the material composition of ICs and package supports may result in differential expansion and contraction of the ICs and package supports due to heat generated during operation (as well as the heat applied during various manufacturing operations). To mitigate damage caused by this differential expansion and contraction (e.g., cracking, solder bridging, etc.), the DTPS interconnects in any of the packages as described herein may be formed larger and farther apart than DTD interconnects, which may experience less thermal stress due to the greater material similarity of the pair of dies on either side of the DTD interconnects.

Note that FIG. 1 is intended to show relative arrangements of the components within their assemblies, and that, in general, such assemblies may include other components that are not illustrated (e.g., various interfacial layers or various other components related to optical functionality, electrical connectivity, or thermal mitigation). For example, in some further embodiments, the assembly as shown in FIG. 1 may include more dies along with other electrical components. Additionally, although some components of the assemblies are illustrated in FIG. 1 as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

FIG. 2 is a schematic exploded view of a microelectronic assembly 200 according to an embodiment of the present disclosure. Die 102 may comprise one or more blockage region 114 (e.g., 114(1), 114(2), 114(3)). One or more JOD 116 (e.g., 116(1), 116(2), 116(3)) may be coupled to die 102 proximate to blockage region 114. In some embodiments, a particular one of JOD 116 may be located proximate to a particular one of blockage region 114; in some other embodiments, a particular one of JOD 116 may be located proximate to more than one blockage region 114. For example, in the figure, JOD 116(1) is located proximate to a single blockage region 114(1), whereas JOD 116(2) is located proximate to blockage regions 114(2) and 114(3). By situating JOD 116 at targeted locations, for example, proximate to blockage region 114, processing costs and other negative impacts may be avoided as compared to attaching another die similarly sized to die 102. JOD 116 may be located in insulator 142, which includes TDVs 144. Bond pads 134 on surface 136 may facilitate connections to other components, such as package support 130.

Conductive pathways (not shown) may be facilitated around blockage region 114 by electrically coupling conductive traces 108 in die 102 through portion 148 of DTD interconnects 118 to conductive traces 122 in JOD 116. In the embodiment shown in the figure, portion 148 of DTD interconnects 118 is shown located proximate to a periphery 202 of blockage region 114 on die 102. Because blockage region 114 is a three-dimensional volume, and DTD interconnects 118 are located on a surface 204 of die 102, periphery 202 of blockage region 114 formed by a projection of the three-dimensional volume on surface 204 is a linear perimeter. In the figure only portion 148 of DTD interconnects 118 is shown so as not to clutter the drawing. JOD 116 may be coupled to die 102 with additional DTD interconnects 118 not shown in the drawing that serve other purposes, for example, mechanical stability, electrical coupling for other reasons, etc.

In various embodiments, during a design phase of microelectronic assembly 200, conductive pathways are laid out in die 102 around blockage region 114 suitably. Selected conductive pathways are rerouted, for example, through suitable conductive vias located at periphery 202 of blockage region 114 to selected bond pads on surface 204 of die 102. JOD 116 is correspondingly designed and laid out to electrically couple selected bond pads thereon with suitable conductive traces 122 in JOD 116. During manufacture, JOD 116 is placed on die 102 so that the selected bond pads of both components are reasonably aligned with each other. When JOD 116 is bonded to die 102, bond pads 119 of die 102 and JOD 116 are fused to form DTD interconnects 118; the selected bond pads around periphery 202 of blockage region 114 correspondingly form portion 148 of DTD interconnects 118 so that the selected conductive pathways in die 102 are routed into and out of JOD 116 around blockage region 114 during operation. This additional “vertical” rerouting at selected locations without a taller metallization stack across the entirety of die 102 can enable a smaller size for die 102 at cheaper costs.

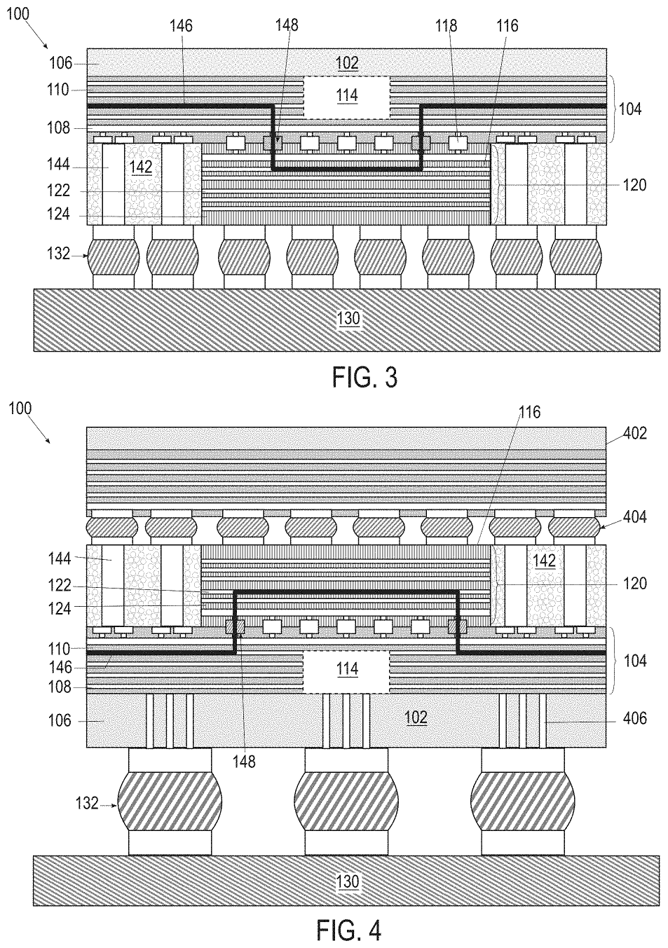

FIG. 3 is a schematic cross-sectional illustration of IC package 100, according to some embodiments of the present disclosure. In the embodiment shown, JOD 116 does not have a substrate and comprises merely metallization stack 120. In such embodiments, after JOD 116 has been bonded to die 102, any substrate on which metallization stack 120 was disposed may no longer be needed, for example, because bonding provides sufficient mechanical stability to metallization stack 120. In such embodiments, a substantial portion of the substrate may be removed, for example, using a suitable thinning or polishing process. Such embodiments may advantageously decrease the overall height of IC package 100 (i.e., the dimension measured along a vertical axis for the examples shown in the present drawing).

In other embodiments, metallization stack 120 may be over die 102 using layer transfer, in which case as metallization stack 120 is placed over die 102 for bonding, any substrate has been already substantially removed. In one particular example of layer transfer, metallization stack 120 may be formed over a carrier wafer provided with a release layer (also called a debonding layer). After die 102 is bonded to metallization stack 120, the carrier wafer may be de-bonded from metallization stack 120 by removing the release layer. In some embodiments, substrate 106 of die 102 may also be substantially removed thus.

FIG. 4 is a schematic cross-sectional illustration of IC package 100, according to some embodiments of the present disclosure. In the embodiment shown, die 102 and JOD 116 are sandwiched between another die 402 and package support 130. In such embodiments, die 102 may function as an “interposer.” JOD 116 may be coupled to die 402 with DTD interconnects 404. In some embodiments, DTD interconnects 404 may comprise micro-bumps. Die 102 may be coupled to package interposer 130 with DTPS interconnects 132. Die 102 may have TSVs 406 to enable electrical connectivity from metallization stack 104 to DTPS interconnects 132. Die 102 may also be electrically coupled to die 402 with TDVs 144 through insulator 142. In the architecture shown in the figure, die 102 is coupled to JOD 116 along its “frontside” and to package support 130 along opposing “backside.” JOD 116 may be coupled to die 102 along its frontside and to die 402 along its backside or vice versa. Die 402 may be coupled to JOD 116 along its frontside. Thus, the arrangement may include front-to-front bonding, front-to-back bonding and/or back-to-back bonding. In various embodiments, JOD 116 may also facilitate routing conductive pathways from die 402 to package support 130 avoiding blocked region 114 in die 102.

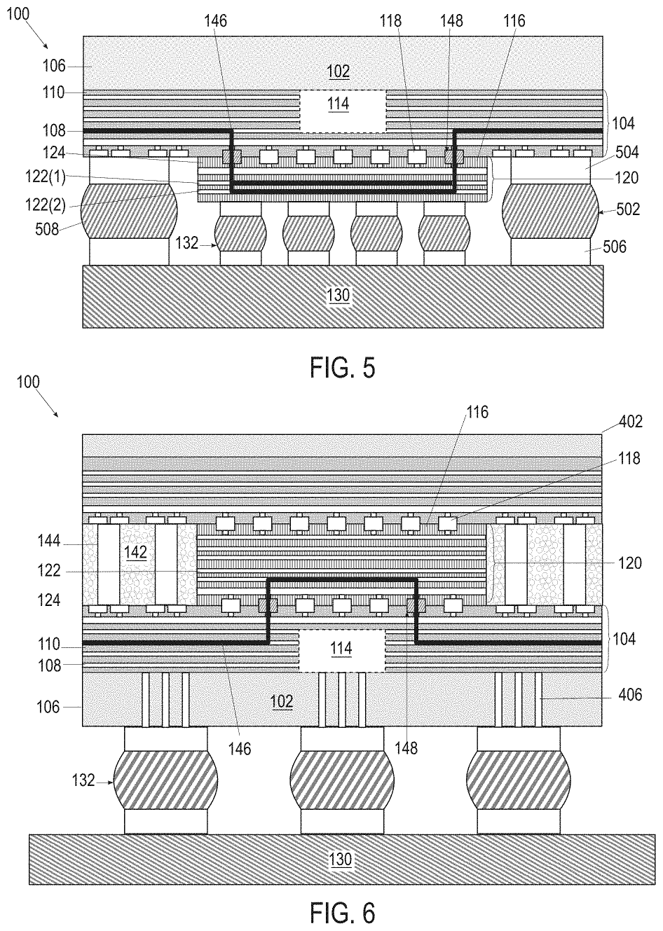

FIG. 5 is a schematic cross-sectional illustration of IC package 100, according to some embodiments of the present disclosure. In the embodiment shown, die 102 is coupled to package support 130 through DTPS interconnects 502 and JOD 116 may be coupled to package support 130 through DTPS interconnects 132. DTPS interconnect 502 may comprise bond pads 504 on die 102, bond pads 506 on package support 130 and solder balls 508 in some embodiments. In the embodiment shown, DTPS interconnects 132 and 502 have different sizes and pitches. In other embodiments, DTPS interconnects 132 and 502 may have similar sizes and pitches. In the embodiment shown, JOD 116 does not comprise substrate 126; in other embodiments, substrate 126 may be present appropriately thinned so that the overall distance between die 102 and package 130 can facilitate interconnects 502 of suitable size and pitch. In some embodiments, underfill (not shown) may be present around JOD 116 and interconnects 132 and 502 to provide mechanical support and increase reliability.

In the example embodiment shown in the figure conductive pathway 146 comprises conductive trace 108 in one metal layer of metallization stack 104 in die 102 and conductive traces 122(1) and 122(2) in two separate layers of metallization stack 120 in JOD 116 for various reasons, such as decreasing routing density in individual layers in JOD 116, for example. Such an arrangement may be implemented in any of the embodiments described herein.

FIG. 6 is a schematic cross-sectional illustration of IC package 100, according to some embodiments of the present disclosure. In the embodiment shown, die 102 and JOD 116 are sandwiched between another die 402 and package support 130. In such embodiments, die 102 may function as an “interposer.” JOD 116 may be coupled to die 402 with DTD interconnects 118. Die 102 may be coupled to package interposer 130 with DTPS interconnects 132. Die 102 may have TSVs 406 to enable electrical connectivity from metallization stack 104 to DTPS interconnects 132. Die 102 may also be electrically coupled to die 402 with TDVs 144 through insulator 142. In such embodiments, JOD 116 may also facilitate rerouting conductive pathways in both dies 102 and 402 through respective portions of corresponding DTD interconnects 118.

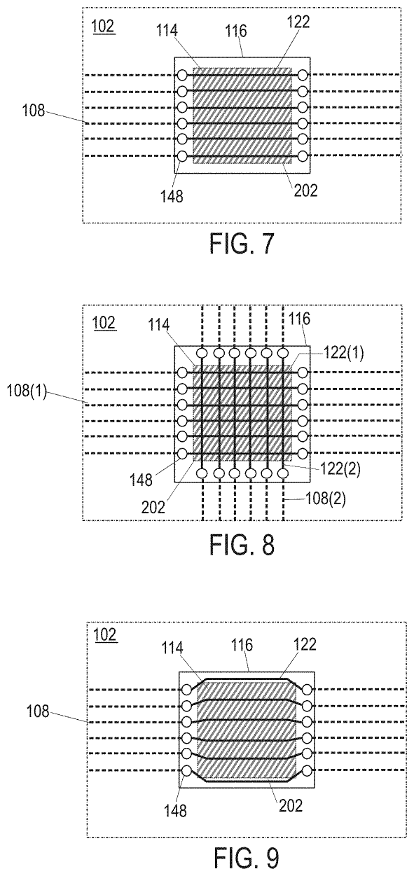

FIG. 7 is a simplified top view of an example routing scheme in microelectronic assembly 200 according to some embodiments of the present disclosure. Conductive trace 108 in die 102 and conductive trace 122 in JOD 116 may be electrically coupled to portion 148 of DTD interconnects 118 located proximate to periphery 202 of blockage region 114. In the embodiment shown, conductive trace 122 is routed substantially parallel to conductive trace 108 in a unidirectional routing architecture.

FIG. 8 is a simplified top view of an example routing scheme in microelectronic assembly 200 according to some embodiments of the present disclosure. Conductive traces 108(1) and 108(2) in die 102 may be in two separate metal layers in metallization stack 104. In the embodiment shown, conductive traces 108(1) and 108(2) are routed substantially orthogonal to each other. Likewise, conductive traces 122(1) and 122(2) in JOD 116 may be in two separate metal layers in metallization stack 120. In the embodiment shown, conductive traces 122(1) and 122(2) are routed substantially orthogonal to each other. Conductive trace 108(1) may be electrically coupled to conductive trace 122(1) and conductive trace 108(2) may be electrically coupled to conductive trace 122(2) with portion 148 of DTD interconnects 118 located proximate to periphery 202 of blockage region 114. In various embodiments, conductive trace 108(1) and conductive trace 122(1) may have the same routing density, which may be different from the routing density of conductive traces 108(2) and 122(2).

FIG. 9 is a simplified top view of an example routing scheme in microelectronic assembly 200 according to some embodiments of the present disclosure. Conductive trace 108 in die 102 and conductive trace 122 in JOD 116 may be electrically coupled with portion 148 of DTD interconnects 118 located proximate to periphery 202 of blockage region 114. In the embodiment shown, the routing density of conductive trace 122 less than the routing density of conductive trace 108 because of the fan-out of conductive trace 122 as shown schematically in the drawing.

In various embodiments, any of the features discussed with reference to any of FIGS. 1-9 herein may be combined with any other features to form a package with one or more ICs as described herein, for example, to form a modified IC package 100 or a modified microelectronic assembly 200. Some such combinations are described above, but, in various embodiments, further combinations and modifications are possible.

### Example Methods

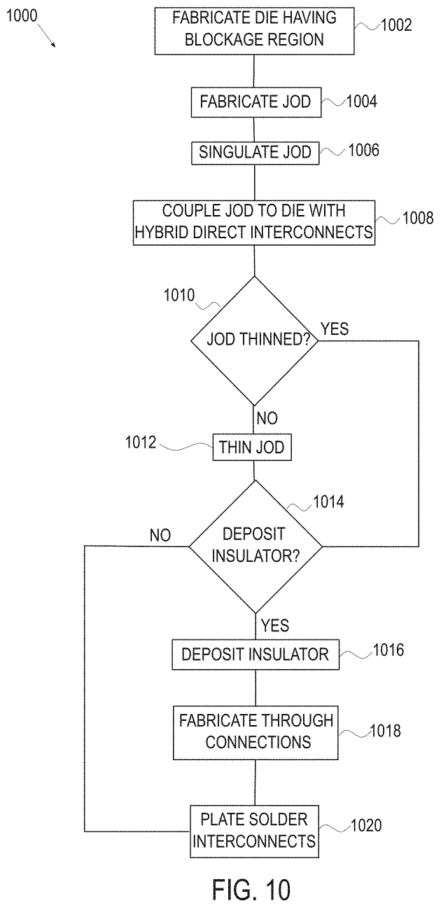

FIG. 10 is a flow diagram of an example method 1000 of fabricating a microelectronic assembly 200, according to various embodiments of the present disclosure. Although FIG. 10 illustrates various operations performed in a particular order, this is simply illustrative, and the operations discussed herein may be reordered and/or repeated as suitable. Further, additional processes which are not illustrated may also be performed without departing from the scope of the present disclosure. Also, various ones of the operations discussed herein with respect to FIG. 10 may be modified in accordance with the present disclosure to fabricate others of microelectronic assembly 200 disclosed herein.

At 1002, die 102 having blockage region 114 may be fabricated on a semiconductor wafer using known methods in the art. At 1004, JOD 116 may be fabricated on a semiconductor wafer in some embodiments or on a carrier wafer or reconstituted wafer in other embodiments. In some embodiments, JOD 116 may be fabricated separately from die 102, for example, at different manufacturing facilities, by different companies, etc. In some embodiments, JOD 116 may be fabricated separately from die 102, for example on a separate carrier wafer. In yet other embodiments, JOD 116 and die 102 may be fabricated on the same semiconductor wafer. At 1006, JOD 116 may be singulated from the wafer into individual dies.

At 1008, JOD 116 may be coupled to die 102, for example, with DTD interconnects 118. In some embodiments, bonding of die 102 and JOD 116 may be performing using insulator-insulator bonding, e.g., as oxide-oxide bonding, where plurality of insulating layers 110 of die 102 is bonded to plurality of insulating layers 124 of JOD 116 followed by metal-metal bonding during which bond pads 119 of die 102 and JOD 116 fuse together to form DTD interconnects 118. In some embodiments, more than one JOD 116 may be bonded to die 102 at appropriate locations, for example, proximate to different blockage region 114 in die 102.

The bonding process may include applying a suitable pressure and heating the assembly to a suitable temperature (e.g., to moderately high temperatures, e.g., between about 50 and 200 degrees Celsius) for a duration of time. In some embodiments, a bonding material may be applied between die 102 and JOD 116 that are bonded together. The bonding material may be an adhesive that ensures attachment of die 102 to JOD 116 in some embodiments. In other embodiments, the bonding material may be an etch-stop material. In yet other embodiments, the bonding material may be both an etch-stop material and have suitable adhesive properties to ensure attachment of die 102 and JOD 116 to one another. In yet other embodiments, no bonding material may be used, in which case, the bonding interface may be recognizable as a seam or a thin layer in microelectronic assembly 200, using, e.g., selective area diffraction (SED), even when the specific materials of the insulators of die 102 and JOD 116 that are bonded together may be the same. In the latter case, the bonding interface may be noticeable as a seam or a thin layer in what otherwise appears as a bulk insulator (e.g., bulk oxide) layer.

At 1010, a determination may be made whether to thin JOD 116. In some embodiments, a thin die may be preferred, for example, to reduce the thickness of microelectronic assembly 200. If so, at 1012, JOD 116 may be thinned. In some embodiments, the thinning may be performed by a polishing process of the backside of substrate 126 of JOD 116. In some other embodiments where JOD 116 is fabricated atop a carrier wafer, the thinning may be performed by releasing the carrier wafer.

If JOD is not to be thinned, or has already been thinned, the operations step to 1014 at which a determination is made whether to deposit insulator 142 around JOD 116. If insulator 142 is to be deposited, at 1016, insulator 142 is deposited around JOD 116. In some embodiments, insulator 142 may be deposited in liquid form and solidified by a curing process using ultraviolet rays or heat. At 1018, through-connections (e.g., TDVs 144) may be formed. In various embodiments, TDV 144 may be formed by planarizing insulator 142, lithographically etching it, followed by electrodeposition of a conductive material such as copper.

If insulator 142 is not to be deposited, or has already been formed, the operations step to 1020 at which solder interconnects may be appropriately plated. For example, bond pads 134 of DTPS interconnects 132 may be formed in this process in some embodiments. In other embodiments, bond pads of DTD interconnects 404 may be formed in this process. Thereafter, additional processing steps may be performed, such as thinning and singulation of die 102, attaching as interposer to die 402, or attaching to package support 130, etc.

Although the operations of method 1000 are illustrated in FIG. 10 once each and in a particular order, the operations may be performed in any suitable order and repeated as desired. For example, one or more operations may be performed in parallel to manufacture multiple IC packages substantially simultaneously. In another example, the operations may be performed in a different order to reflect the structure of a particular IC package in which one or more microelectronic assembly 200 as described herein may be included. In yet another example, insulator 142 may be deposited around JOD 116 before attachment to die 102, for example, in a reconstituted wafer process. In yet another example, JOD 116 may be thinned before bonding to die 102. Numerous other variations are also possible to achieve the desired structure of microelectronic assembly 200.

Furthermore, the operations illustrated in FIG. 10 may be combined or may include more details than described. Still further, method 1000 shown in FIG. 10 may further include other manufacturing operations related to fabrication of other components of the microelectronic assemblies described herein, or any devices that may include microelectronic assemblies as described herein. For example, method 1000 may include various cleaning operations, surface planarization operations (e.g., using CMP), operations for surface roughening, operations to include barrier and/or adhesion layers as desired, and/or operations for incorporating packages as described herein in, or with, an IC component, a computing device, or any desired structure or device.

### Example Devices and Components

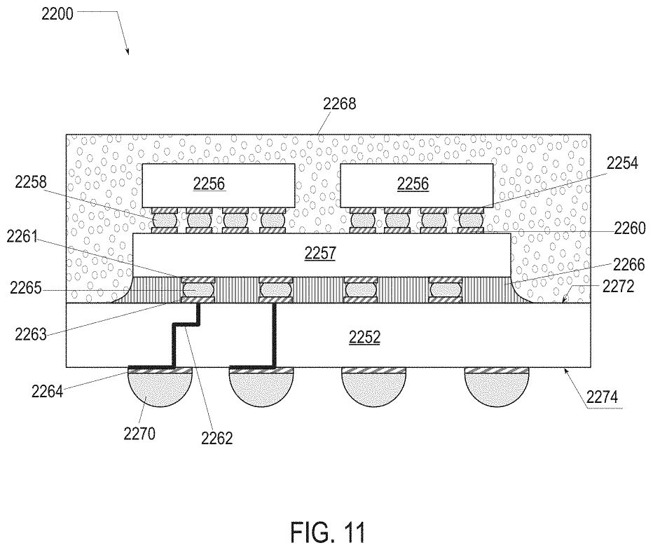

The packages disclosed herein, e.g., any of the embodiments shown in FIGS. 1-9 or any further embodiments described herein, may be included in any suitable electronic component. FIGS. 11-13 illustrate various examples of packages, assemblies, and devices that may be used with or include any of the IC packages as disclosed herein.

FIG. 11 is a side, cross-sectional view of an example IC package 2200 that may include IC packages in accordance with any of the embodiments disclosed herein. In some embodiments, the IC package 2200 may be a system-in-package (SiP).

As shown in FIG. 11, package support 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias, e.g., as discussed above with reference to FIG. 1.

Package support 2252 may include conductive contacts 2263 that are coupled to conductive pathway 2262 through package support 2252, allowing circuitry within dies 2256 and/or interposer 2257 to electrically couple to various ones of conductive contacts 2264 (or to other devices included in package support 2252, not shown).

IC package 2200 may include interposer 2257 coupled to package support 2252 via conductive contacts 2261 of interposer 2257, first-level interconnects 2265, and conductive contacts 2263 of package support 2252. First-level interconnects 2265 illustrated in FIG. 11 are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). First-level interconnects 2258 illustrated in FIG. 11 are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

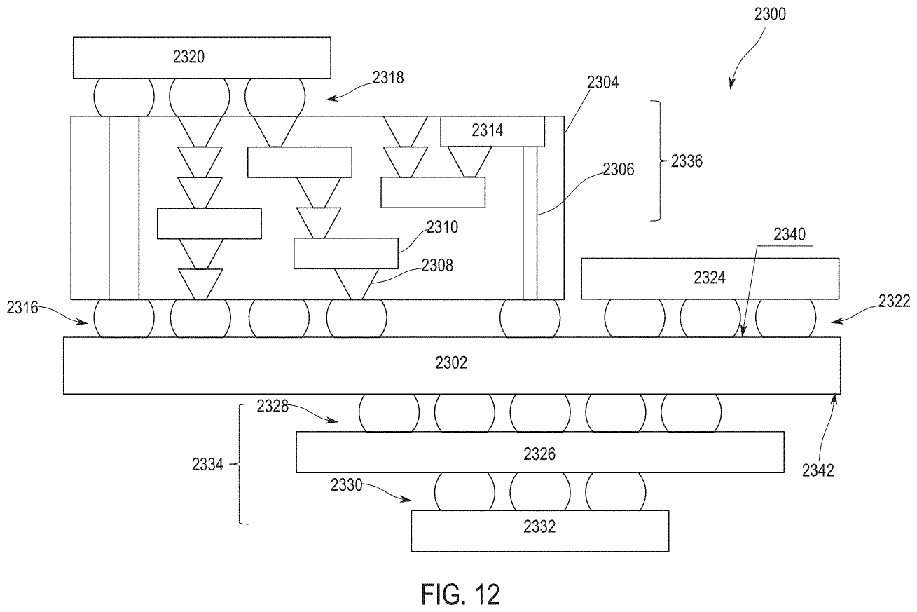

In some embodiments, underfill material 2266 may be disposed between package support 2252 and interposer 2257 around first-level interconnects 2265, and mold 2268 may be disposed around dies 2256 and interposer 2257 and in contact with package support 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in FIG. 11 are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 12.

In various embodiments, any of dies 2256 may include JOD 116 as described herein. In embodiments in which IC package 2200 includes multiple dies 2256, IC package 2200 may be referred to as a multi-chip package (MCP). Dies 2256 may include circuitry to perform any desired functionality. For example, besides one or more of dies 2256 being JOD 116 as described herein, one or more of dies 2256 may be logic dies (e.g., silicon-based dies), one or more of dies 2256 may be memory dies (e.g., high-bandwidth memory), etc. In some embodiments, at least some of dies 2256 may not include JOD 116 as described herein.

Although IC package 2200 illustrated in FIG. 11 is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package support 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

FIG. 12 is a cross-sectional side view of an IC device assembly 2300 that may include components having one or more microelectronic assembly 200 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 200 in accordance with any of the embodiments disclosed herein; e.g., any of the IC packages discussed below with reference to IC device assembly 2300 may take the form of any of the embodiments of IC package 2200 discussed above with reference to FIG. 11.

In some embodiments, circuit board 2302 may be a printed circuit board (PCB) including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package support.

FIG. 12 illustrates that, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 11. In some embodiments, IC package 2320 may include at least one JOD 116 as described herein. JOD 116 is not specifically shown in FIG. 12 in order to not clutter the drawing.

Although a single IC package 2320 is shown in FIG. 12, multiple IC packages may be coupled to interposer 2304; indeed, additional interposers may be coupled to interposer 2304. Interposer 2304 may provide an intervening package support used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in FIG. 12, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

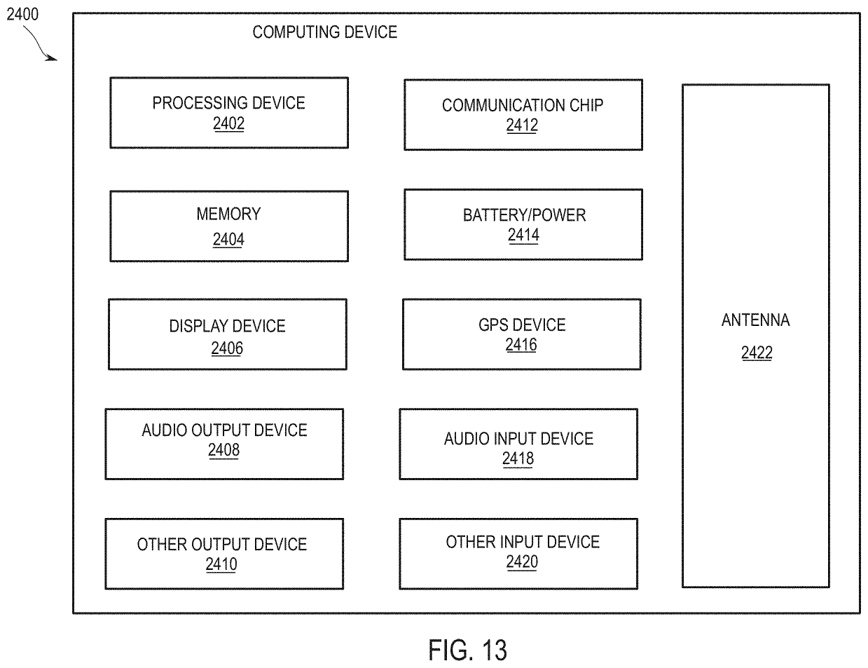

FIG. 13 is a block diagram of an example computing device 2400 that may include one or more components having one or more IC packages in accordance with any of the embodiments disclosed herein. For example, any suitable ones of the components of computing device 2400 may include a microelectronic assembly with a JOD (e.g., 116), in accordance with any of the embodiments disclosed herein. In another example, any one or more of the components of computing device 2400 may include any embodiments of IC package 2200 (e.g., as shown in FIG. 11). In yet another example, any one or more of the components of computing device 2400 may include an IC device assembly 2300 (e.g., as shown in FIG. 12).

A number of components are illustrated in FIG. 13 as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single system-on-a-chip (SoC) die.

Additionally, in various embodiments, computing device 2400 may not include one or more of the components illustrated in FIG. 13, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more digital signal processors (DSPs), ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-MRAM).

In some embodiments, computing device 2400 may include a communication chip 2412 (e.g., one or more communication chips; note that the terms “chip,” “die,” and “IC die” are used interchangeably herein). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

### Select Examples

The following paragraphs provide various examples of the embodiments disclosed herein.

Example 1 provides an IC comprising a first conductive trace (e.g., 108 in FIG. 1) on a first die (e.g., 102), a second conductive trace (e.g., 122) on a second die (e.g., 116) coupled to the first die with interconnects (e.g., 118), and a conductive pathway (e.g., 146) electrically coupling the first conductive trace with the second conductive trace. The conductive pathway comprises a portion (e.g., 148) of the interconnects located proximate to a periphery (e.g., 202 in FIG. 2) of a region (e.g., 114) in the first die through which the first conductive trace is not routable.

Example 2 provides the IC of example 1 in which the second die is smaller than the first die.

Example 3 provides the IC of any of examples 1-2, in which the IC comprises a plurality of blocked regions (e.g., 114(1), 114(2), 114(3) FIG. 2), and a plurality of second dies (e.g., 116(1), 116(2), 116(3)) is coupled to the IC proximate to the plurality of blocked regions such that conductive pathways avoiding the plurality of blocked regions are enabled in the IC by electrically coupling conductive traces in the first die with conductive traces in the plurality of second dies through a portion of the interconnects located proximate to peripheries of the plurality of blocked regions.

Example 4 provides the IC of any of examples 1-3 in which the IC comprises a plurality of blocked regions (e.g., 14(2), 114(3) in FIG. 2) and the second die (e.g., 116(2)) is coupled to the first die proximate to the plurality of blocked regions such that conductive pathways avoiding the plurality of blocked regions are enabled in the IC by electrically coupling conductive traces in the first die with conductive traces in the second die through a portion of the interconnects located proximate to peripheries of the plurality of blocked regions.

Example 5 provides the IC of any of examples 1-4, in which the second die is electrically coupled to a package support (e.g., 130).

Example 6 provides the IC of any of examples 1-5, in which the first die is electrically coupled to the package support with conductive TDVs (e.g., TDVs 144) in an insulator (e.g., 142) surrounding the second die, and the TDVs and the second die are electrically coupled to the package support with DTPS interconnects (e.g., 132).

Example 7 provides the IC of any of examples 1-5, in which the first die and second die are electrically coupled to the package support with DTPS interconnects (e.g., FIG. 5).

Example 8 provides the IC of any of examples 1-6, in which the second die comprises a metallization stack (e.g., 120) without a substrate (e.g., FIG. 3).

Example 9 provides the IC of any of examples 1-7, in which the second die comprises a metallization stack (e.g., 120) with a substrate (e.g., 126).

Example 10 provides the IC of example 9, in which the substrate comprises TSVs (e.g., 128 in FIG. 1).

Example 11 provides the IC of example 9, in which the substrate comprises silicon.

Example 12 provides the IC of example 9, in which the substrate comprises glass.

Example 13 provides the IC of example 9, in which the substrate comprises one of Group III-V semiconductors.

Example 14 provides the IC of example 9, in which the substrate comprises silica-filled epoxy.

Example 15 provides the IC of any of examples 1-14, in which the metallization stack of the second die comprises conductive metal layers (e.g., 122) in insulating layers (e.g., 124).

Example 16 provides the IC of any of examples 1-15, in which the insulator of the metallization stack of the second die comprises an inorganic dielectric.

Example 17 provides the IC of any of examples 1-15, in which the insulator of the metallization stack of the second die comprises an organic dielectric.

Example 18 provides the IC of any of examples 1-15, in which the insulator of the metallization stack of the second die comprises a low-k dielectric.

Example 19 provides the IC of any of examples 1-18, in which the first die comprises a metallization stack (e.g., 104) without a substrate.

Example 20 provides the IC of any of examples 1-19, in which the second die is electrically coupled to a third die (e.g., 402 in FIG. 4, FIG. 6).

Example 21 provides the IC of any of examples 1-19, in which the first die is electrically coupled to the third die with TDVs in an insulator surrounding the second die.

Example 22 provides the IC of any of examples 20-21, in which the TDVs and the second die are electrically coupled to the third die with DTD interconnects (e.g., 406 in FIG. 4).

Example 23 provides the IC of any of examples 20-22, in which the TDVs and the second die are electrically coupled to the third die with interconnects (e.g., 118 in FIG. 6).

Example 24 provides the IC of any of examples 20-23, in which the first die is electrically coupled to a package support with DTPS interconnects (e.g., FIGS. 4-6).

Example 25 provides the IC of any of examples 1-24, in which the IC further comprises a third conductive trace in the second die electrically coupled to the first conductive trace and the second conductive trace by the conductive pathway (e.g., FIG. 5). The second conductive trace is in a first metal layer of the second die, and the third conductive trace is in a different second metal layer of the second die.

Example 26 provides a microelectronic assembly, comprising a first die (e.g., 102) having a blockage region (e.g., 114) extending through a first metallization stack (e.g., 104), and a second die (e.g., 116) with a second metallization stack (e.g., 120) is electrically and mechanically coupled to the first die with interconnects (e.g., 118). A first conductive trace (e.g., 108) in the first metallization stack is electrically coupled to a second conductive trace (e.g., 122) in the second metallization stack by a conductive pathway (e.g., 146) through a portion (e.g., 148) of the interconnects located proximate to a periphery (e.g., 202 in FIG. 2) of the blockage region.

Example 27 provides the microelectronic assembly of example 26, in which the blockage region comprises a high congestion zone having high routing density.

Example 28 provides the microelectronic assembly of any of examples 26-27, in which the microelectronic assembly further comprises an insulator (e.g., 142) surrounding the second die, in which respective surfaces of the insulator and the second die opposite to the first die comprise conductive bond pads (e.g., 134), and conductive TDVs (e.g., 144) through the insulator configured to provide electrical coupling between the first die and at least some of the bond pads.

Example 29 provides the microelectronic assembly of any of examples 26-28, in which the microelectronic assembly further comprises a third conductive trace (e.g., 108(2) in FIG. 8) in the first metallization stack, and a fourth conductive trace (e.g., 122(2) in FIG. 8) in the second metallization stack. The third conductive trace is orthogonal to the first conductive trace (e.g., 108(1) in FIG. 8), the fourth conductive trace is orthogonal to the second conductive trace (e.g., 122(1) in FIG. 8), the conductive pathway comprises a first conductive pathway, and the third conductive trace is electrically coupled to the fourth conductive trace by a second conductive pathway through another portion of the interconnects located proximate to the periphery of the blockage region.

Example 30 provides the microelectronic assembly of any of examples 26-29, in which the first conductive trace comprises a first plurality of conductive traces, the second conductive trace comprises a second plurality of conductive traces, and the second plurality of conductive traces is parallel to the first plurality of conductive traces (e.g., FIG. 7).

Example 31 provides the microelectronic assembly of any of examples 26-30, in which the second plurality of conductive traces has a lower routing density than the first plurality of conductive traces (e.g., FIG. 9).

Example 32 provides a method (e.g., FIG. 10) for fabricating a microelectronic assembly (e.g., 200) comprising fabricating a first die on a wafer, the first die having a blockage region, fabricating a second smaller die, and coupling the second die to the first die with interconnects proximate to the blockage region. A first conductive trace in the first die is electrically coupled to a second conductive trace in the second die through a portion of the interconnects such that the first conductive trace is routed away from the blockage region.

Example 33 provides the method of example 32, further comprising disposing insulator (e.g., 142) around the second die, and forming TDVs (e.g., 144) in the insulator.

Example 34 provides the method of any of examples 31-33, in which the second die comprises a metallization stack (e.g., 120) on a substrate (e.g., 126), the method further comprising thinning the second die such that the substrate is removed.

Example 35 provides a method (e.g., FIG. 10) of fabricating a microelectronic assembly (e.g., 200). The method includes providing a carrier wafer and disposing metallization (e.g., 120) on the carrier wafer. The method further includes providing conductive contact areas on the bottom-most layer of the metallization and bond pads on the top-most layer of the metallization.

Example 36 provides a method according to example 35, further including depositing an insulator (e.g., 142) around the metallization, curing the insulator, etching holes in the insulator, and electroplating metal in the etched holes to form TDVs in the insulator.

Example 37 provides a method according to example 35, further including depositing metal pillars on the carrier wafer around the metallization, followed by spinning an insulator around the metal pillars and the metallization and curing the insulator such that the metal pillars form TDVs in the insulator.

Example 38 provides the method according to any of examples 35-37, further including attaching a die (e.g., 102) on the metallization at the bond pads such that the die and the metallization are electrically and mechanically coupled with interconnects.

Example 39 provides a method according to any of examples 35-38, further including forming conductive bond pads on the insulator and the metallization. Forming conductive bond pads includes removing the carrier wafer to expose respective surfaces of the insulator and the metallization and electroplating conductive metal on the TDVs and the conductive contact areas of the respective surfaces.

Example 40 provides a method (e.g., FIG. 10) of fabricating a microelectronic assembly (e.g., 200). The method includes providing a first wafer comprising a first plurality of dies (e.g., 102) having blockage regions (e.g., 114) therein. A front surface of the first plurality of dies comprises bond pads (e.g., 119) including a portion located around peripheries of the blockage regions.

Example 41 provides the method of example 40, further comprising providing a second wafer comprising a second plurality of dies (e.g., 116) surrounded by an insulator (e.g., 142) having TDVs (e.g., 144) interspersed therein. A front surface of the second plurality of dies comprises bond pads corresponding to the bond pads on the first plurality of dies, including a second portion of bond pads corresponding to the first portion of bond pads.

Example 42 provides the method of example 41 further including bonding the first wafer to the second wafer such that the bond pads of the first plurality of dies fuse with the bond pads of the second plurality of dies to form interconnects (e.g., 118). The first portion of bond pads on the first plurality of dies bonds with the second portion of bond pads on the second plurality of dies such that a portion of the interconnects formed therefrom enable conductive pathways that avoid the blockage regions.

Example 43 provides the method of example 42, further comprising removing the second wafer.

Example 44 provides the method of example 43, further comprising singulating the first wafer into individual microelectronic assemblies (e.g., 200).

Example 45 provides the method of any of examples 42-44, further comprising providing the conductive pathways through the portion of the interconnects.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. An Integrated Circuit (IC), comprising:
a first conductive trace in a first die;
a second conductive trace in a second die; and
a conductive pathway electrically coupling the first conductive trace with the second conductive trace, wherein:
the second die is coupled to the first die with interconnects, and
the conductive pathway comprises a portion of the interconnects located proximate to a periphery of a region in the first die through which the first conductive trace is not routable.

2. The IC of claim 1, wherein the interconnects comprise hybrid bond interconnects.

3. The IC of claim 1, wherein the second die is electrically coupled to a package support.

4. The IC of claim 3, wherein:
the first die is electrically coupled to the package support with conductive through-dielectric vias (TDVs) in an insulator surrounding the second die, and
the TDVs and the second die are electrically coupled to the package support with die-to-package-substrate (DTPS) interconnects.

5. The IC of claim 3, wherein the first die and second die are electrically coupled to the package support with DTPS interconnects.

6. The IC of claim 1, wherein the second die is electrically coupled to a third die.

7. The IC of claim 6, wherein the first die is electrically coupled to the third die with TDVs, wherein an insulating material surrounds the second die, and the TDVs are at least partially located in the insulating material.

8. The IC of claim 7, wherein the TDVs and the second die are electrically coupled to the third die with die-to-die (DTD) interconnects.

9. The IC of claim 7, wherein the TDVs and the second die are electrically coupled to the third die with hybrid bond interconnects.

10. The IC of claim 6, wherein the first die is electrically coupled to a package support with DTPS interconnects.

11. The IC of claim 1, further comprising a third conductive trace in the second die electrically coupled to the first conductive trace and the second conductive trace by the conductive pathway, wherein:
the second conductive trace is in a first metal layer of the second die, and
the third conductive trace is in a different second metal layer of the second die.

12. A microelectronic assembly, comprising:
a first die having a blockage region extending through a first metallization stack; and
a second die electrically and mechanically coupled to the first die with a plurality of interconnects, wherein:
the second die comprises a second metallization stack,
a first conductive trace in the first metallization stack is electrically coupled to a second conductive trace in the second metallization stack by a conductive pathway through a portion of the plurality of interconnects, and
the portion of the plurality of interconnects is located proximate to a periphery of the blockage region.

13. The microelectronic assembly of claim 12, wherein the blockage region comprises a high congestion zone having high routing density.

14. The microelectronic assembly of claim 12, further comprising:
an insulating material surrounding the second die, wherein respective surfaces of the insulating material and the second die opposite to the first die comprise conductive bond pads; and
conductive TDVs through the insulating material configured to provide electrical coupling between the first die and at least some of the bond pads.

15. The microelectronic assembly of claim 12, further comprising:
a third conductive trace in the first metallization stack; and
a fourth conductive trace in the second metallization stack, wherein:
the third conductive trace is orthogonal to the first conductive trace,
the fourth conductive trace is orthogonal to the second conductive trace,
the conductive pathway comprises a first conductive pathway, and
the third conductive trace is electrically coupled to the fourth conductive trace by a second conductive pathway through another portion of interconnects located proximate to the periphery of the blockage region.

16. The microelectronic assembly of claim 12, wherein:
the first conductive trace comprises a first plurality of conductive traces,
the second conductive trace comprises a second plurality of conductive traces, and
the second plurality of conductive traces is parallel to the first plurality of conductive traces.

17. The microelectronic assembly of claim 16, wherein the second plurality of conductive traces has a lower routing density than the first plurality of conductive traces.

18. A method comprising:
fabricating a first die on a wafer, wherein the first die comprises a blockage region;
fabricating a second smaller die; and
coupling the second die to the first die with interconnects proximate to the blockage region, wherein a first conductive trace in the first die is electrically coupled to a second conductive trace in the second die through a portion of the interconnects such that the first conductive trace is routed away from the blockage region.

19. The method of claim 18, further comprising:
disposing organic dielectric around the second die; and
forming through-dielectric vias in the organic dielectric.

20. The method of claim 18, wherein the second die comprises a metallization stack on a substrate, the method further comprising thinning the second die such that the substrate is removed.
